(19) United States
(12) Patent Application Publication
(10) Pub. No.: US 2025/0387968 A1
(43) Pub. Date: Dec. 25, 2025

(54) DEVICE AND METHOD OF BENDING PANEL FOR DISPLAY DEVICE AND DEVICE OF BENDING PANEL FOR ELECTRONIC DEVICE

(71) Applicant: Samsung Display Co., LTD., Yongin-si (KR)

(72) Inventors: Sun Kyun PARK, Yongin-si (KR); JINHO CHOI, Yongin-si (KR); LEEGU HAN, Yongin-si (KR)

(21) Appl. No.: 19/213,145

(22) Filed: May 20, 2025

(30) Foreign Application Priority Data
Jun. 25, 2024 (KR) 10-2024-0082840

(51) Int. Cl. B29C 53/04; B29L 31/34

(52) U.S. Cl. CPC B29C 53/04; B29L 2031/3475

(57) ABSTRACT

A device and method of bending a panel for a display device are disclosed. A device of bending a panel for a display device includes: a plurality of bending members; and a plurality of moving members coupled to the bending members to be movable and configured to mount the panel thereon, and the panel, mounted on the moving members, bends as the bending members are rotated, and a bending position of the panel mounted on the moving members is changed as the moving members are moved.

### CROSS-REFERENCE TO RELATED APPLICATION

The present application claims priority to and the benefit of Korean Patent Application No. 10-2024-0082840, filed on Jun. 25, 2024 in the Korean Intellectual Property Office, the entire disclosure of which is incorporated herein by reference.

### BACKGROUND

### 1. Field

Aspects of embodiments of the present disclosure relate to a device and method of bending a panel for a display device.

### 2. Description of the Related Art

A display device is a device that provides visual information, such as an image to a user, and may be used in any of various electronic devices, such as a computer, a television (TV), a game device, and a mobile phone, for example.

Various types of display devices have been developed that may reduce an overall size thereof while maintaining a screen having a certain size or above for the mobile phone or the like, where mobility is important, among these electronic devices.

A panel for a display device may be manufactured using a flexible material, and may reduce a size thereof by bending the panel.

However, when performing a bending work of bending the panel continuously, the bending work may be delayed due to frequent loading and unloading of the panel.

### SUMMARY

According to an aspect of embodiments of the present disclosure, bending work of a panel for a display device may be facilitated.

According to one or more embodiments, a device of bending a panel for a display device includes: a plurality of bending members; and a plurality of moving members coupled to the bending members to be movable and configured to mount the panel thereon, and configured to mount the panel thereon, wherein the panel, mounted on the moving members, bends as the bending members are rotated, and a bending position of the panel mounted on the moving members is changed as the moving members are moved.

The plurality of bending members may include a first bending member, a second bending member spaced apart from the first bending member in a first direction, and symmetric to the first bending member with respect to a first symmetry axis in a second direction perpendicular to the first direction, a third bending member spaced apart from the first bending member in the second direction, and symmetric to the first bending member with respect to a second symmetry axis in the first direction, and a fourth bending member spaced apart from the third bending member in the first direction, symmetric to the third bending member with respect to the first symmetry axis, spaced apart from the second bending member in the second direction, and symmetric to the second bending member with respect to the second symmetry axis.

The first bending member and the second bending member may be fixed to each other, and may be rotatable about a first rotation axis in the second direction.

The third bending member and the fourth bending member may be fixed to each other, and may be rotatable about a second rotation axis in the second direction.

The plurality of moving members may be between the plurality of bending members.

The plurality of bending members may include a first bending member, a second bending member spaced apart from and parallel to the first bending member in a first direction, a third bending member spaced apart from and parallel to the first bending member in a second direction perpendicular to the first direction, and a fourth bending member spaced apart from and parallel to the third bending member in the first direction, and spaced apart from and parallel to the second bending member in the second direction, and the plurality of moving members may include a first moving member coupled between the first bending member and the second bending member, and a second moving member coupled between the third bending member and the fourth bending member.

The first bending member and the second bending member may be fixed to each other, and may be rotatable about a first rotation axis in the second direction.

The third bending member and the fourth bending member may be fixed to each other, and may be rotatable about a second rotation axis in the second direction.

The first moving member and the second moving member may be movable in the second direction.

A distance between the first moving member and the second moving member may be maintained constant.

A shortest distance between the first moving member and the second moving member may be longer than a shortest distance between the first or the second bending member and the third or the fourth bending member.

A boundary of the first moving member in the second direction may not exceed a boundary of the first or second bending member in the second direction, and a boundary of the second moving member in the second direction may not exceed a boundary of the third or fourth bending member in the second direction.

The device may further include a panel fixing member attached to a surface of the moving member and fixing the panel mounted on the moving member.

According to another embodiment, provided is device of bending a panel for a display device, the device including: a pair of first bending members, and a pair of second bending members on a different surface from the first bending member, wherein the panel, mounted on the first bending member, bends as the first bending member is rotated, the panel, mounted on the second bending member, bends as the second bending member is rotated, and the panel is mounted on the first bending member or the second bending member by being aligned while having different bending positions.

The device may further include: a first panel fixing member attached to a first surface of the first bending member and fixing the panel mounted on the first bending member; and a second panel fixing member attached to a second surface of the second bending member and fixing the panel mounted on the second bending member, wherein the first surface of the first bending member and the second surface of the second bending member are opposite to each other.

The pair of first bending members may be spaced apart from each other in a first direction, and at least one of the pair of first bending members may be rotatable about a rotation axis in a second direction perpendicular to the first direction, and the pair of second bending members may be spaced apart from each other in the first direction, and at least one of the pair of second bending members may be rotatable about the rotation axis in the second direction.

According to one or more embodiments, a method of bending a panel for a display device includes: loading the panel on a moving member coupled to a bending member; bending the panel centering on a first bending position by rotating the bending member; primarily moving the moving member with respect to the bending member; and bending the panel centering on a second bending position, different from the first bending position, by rotating the bending member.

The method may further include secondarily moving the moving member with respect to the bending member, and bending the panel centering on a third bending position, different from the first and second bending positions, by rotating the bending member.

The first bending position may be between the second bending position and the third bending position.

The panel may be fixed to the moving member by a suction pad attached to the moving member.

In one or more embodiments, the bending work may be made simpler and easier than repeatedly loading and transferring the panel by using a robot hand or the like as the bending position of the panel is changed.

### BRIEF DESCRIPTION OF THE DRAWINGS

FIGS. 1A to 1C are schematic views of a device of bending a panel for a display device according to an embodiment of the present disclosure, where FIG. 1A is a plan view and FIGS. 1B and 1C are side views; and FIGS. 1A and 1B show a ready state and FIG. 1C shows a bending state.

FIGS. 2A to 2L are schematic views of an operation of bending the panel for the display device according to an embodiment of the present disclosure, where FIGS. 2A, 2C, 2E, 2G, 2I, and 2K are plan views, and FIGS. 2B, 2D, 2F, 2H, 2J, and 2L are side views.

FIGS. 3A to 3H and FIGS. 4A to 4C are schematic views of a device and method for bending the panel for the display device according to another embodiment of the present disclosure, where FIGS. 3A to 3H are side views and FIGS. 4A to 4C are plan views.

### DESCRIPTION OF SYMBOLS

10, 30: bending device
12, 32, 42: bending member
14: moving member
16, 36, 46: panel fixing member
20, 50: panel

### DETAILED DESCRIPTION

An embodiment of a display device may be applied to various electronic devices. An embodiment of an electronic device may include the display device, and may further include modules or devices having additional functions other than the display device.

A device and method of bending a panel for a display device according to various embodiments of the present disclosure are described in further detail with reference to the accompanying drawings.

In order to describe various members and parts in the drawings, sizes thereof may be enlarged or reduced for reasons of clarity.

When a part (or member) is described as being “on” another part (or member), the corresponding part (or member) may be “directly on” another part (or member), or the corresponding part (or member) may be “above” another part (or member) while having a third part (or member) interposed therebetween.

On the contrary, when a part (or member) is described as being “directly on” another part (or member), there is no third part (or member) interposed therebetween.

In the specification, terms such as “first” and “second” are used as modifiers for subsequent nouns. However, unless clearly defined, these terms are given only based on an order of description, and do not indicate any type of (e.g., defined spatial, temporal, logical) arrangement.

In addition, parts or members having the same or similar functions in two or more drawings may be indicated by the same reference numeral.

However, these indications are provided for simplified illustration and description, and do not necessarily mean that the parts or members indicated by the same reference numerals are completely identical to each other in terms of their structures and functions in all embodiments.

Unless otherwise defined, all (technical and scientific) terms used herein have the same meanings as commonly known by those skilled in the art to which the present disclosure pertains.

Unless otherwise defined herein, a commonly used term should be interpreted as having the meaning used in the related art or having the meaning given in the dictionary, and should not be interpreted as having an overly narrow or formal meaning.

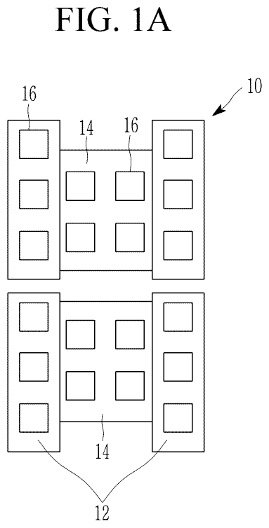

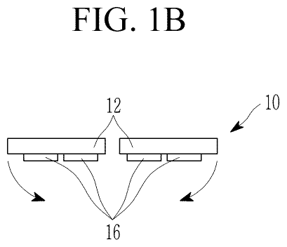

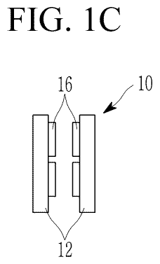

A device of bending a panel for a display device according to an embodiment of the present disclosure is described with reference to FIGS. 1A to 1C.

FIGS. 1A to 1C are schematic views of the device of bending the panel for the display device according to an embodiment of the present disclosure, where FIG. 1A is a plan view and FIGS. 1B and 1C are side views; and FIGS. 1A and 1B show a ready state and FIG. 1C shows a bending state.

Referring to FIGS. 1A to 1C, a device 10 of bending the panel for the display device according to the present embodiment may include: a plurality of bending members 12 (in a bending stage); a plurality of moving members 14 (in a moving stage); and a plurality of panel fixing members 16 coupled to the bending members 12 and the moving members 14.

In an embodiment, the bending members 12 may be a plurality of pairs. For example, referring to FIG. 1A, one pair may be provided at an upper portion of the device 10 and one pair may be provided at a lower portion of the device 10.

Here, as shown in FIG. 1B, the upper portion and the lower portion may refer to the upper and lower portions based on the ground (or a horizontal plane) rather than the upper and lower portions in a direction of gravity.

The upper two bending members 12 may be spaced apart from each other at a distance (for example, in a first direction), and symmetric to each other (for example, with respect to a first symmetry axis in a second direction perpendicular to the first direction).

The upper two bending members 12 may be physically fixed to each other.

For example, the upper two bending members 12 may be fixed to a connection rod (for example, extending in the first direction, not shown) or the like, or may be integrated with the connection rod.

The lower two bending members 12 may respectively be vertically symmetric to the upper two bending members 12.

The lower two bending members 12 may also be physically fixed to each other through the connection rod (not shown) or the like.

For example, referring to FIG. 1A, one moving member 14 may be disposed between the upper two bending members 12 and one moving member 14 may be disposed between the lower two bending members 12.

The moving member 14 may be movably coupled to the two adjacent bending members 12.

For example, referring to FIG. 1A, the upper moving member 14 may be coupled to the upper two bending members 12 to vertically slide.

Similarly, the lower moving member 14 may be coupled to the lower two bending members 12 to vertically slide.

In an embodiment, a shortest distance between the moving members 14 may be longer than a shortest distance between the upper bending member 12 and the lower bending member 12.

An upper or lower boundary of the moving member 14 may not exceed an upper or lower boundary of the corresponding bending member 12.

A distance between the moving members 14 may be fixed, and the two moving members 14 may be moved in a same direction.

That is, referring to FIG. 1A, the upper moving member 14 and the lower moving member 14 may be concurrently or simultaneously moved upward or downward.

In an embodiment, the panel fixing member 16 may include a suction pad, and may be attached to a surface of each of the bending member 12 and the moving member 14, as shown in FIGS. 1A and 1B.

For example, the panel fixing member 16 may fix the panel, on which the bending work is to be performed, by using a method such as suction.

For example, referring to FIGS. 1B and 1C, the upper bending member 12 may be rotated about an axis parallel to a horizontal direction in FIG. 1A.

For example, a rotation axis of the upper bending member 12 may be disposed near a lower end of the upper bending member 12 in FIG. 1A.

For example, the lower bending member 12 may also be rotated about the axis parallel to the horizontal direction in FIG. 1A.

For example, a rotation axis of the lower bending member 12 may be disposed near an upper end of the lower bending member 12 in FIG. 1A.

In an embodiment, as shown in FIG. 1C, the maximum rotation angle of each of the upper and lower bending members 12 may be about 90 degrees.

As the upper and lower bending members 12 are rotated, the moving member 14 coupled thereto may also be rotated.

According to another embodiment of the present disclosure, only one of the upper and lower bending members 12 may be rotated up to about 180 degrees rather than both the upper and lower bending members 12 being rotated.

The bending work may be performed as the panel is loaded to span the upper and lower moving members 14, the panel is fixed to the moving members 14 by using the panel fixing member 16, and then the upper and lower bending members 12 may be rotated such that the panel bends.

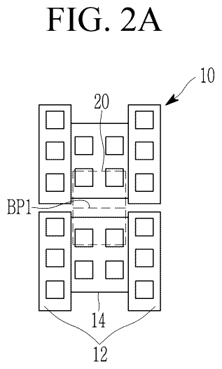

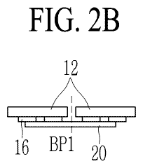

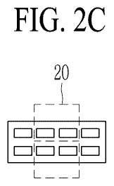

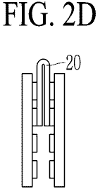

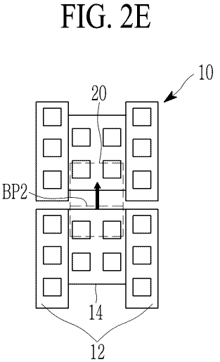

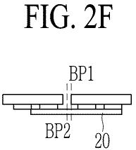

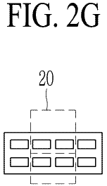

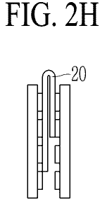

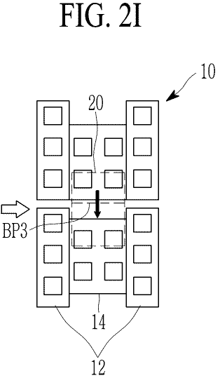

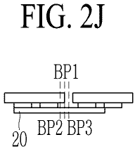

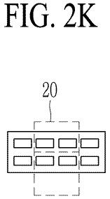

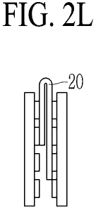

The bending work is described in further detail with reference to FIGS. 2A to 2L.

FIGS. 2A to 2L are schematic views of an operation of bending the panel for the display device according to an embodiment of the present disclosure.

FIGS. 2A, 2C, 2E, 2G, 2I, and 2K are plan views, and FIGS. 2B, 2D, 2F, 2H, 2J, and 2L are side views.

In an embodiment, the bending work may be performed continuously on several bending positions of a panel 20, such as three adjacent points.

First, as shown in FIGS. 2A and 2B, while the upper bending member 12 and the upper moving member 14 are disposed to be parallel to the lower bending member 12 and the lower moving member 14, for example, the panel 20 may be loaded onto the moving member 14 of the bending device 10 by using a robot hand, for example, and the panel 20 may be fixed to the moving member 14 by using the panel fixing member 16 of the moving member 14.

Here, a first bending point of the panel 20 (herein, “the first bending position BP1”) may be aligned at a center between the upper bending member 12 and the lower bending member 12.

For example, a middle position among three bending positions BP1, BP2, and BP3 of the panel 20 may be aligned at the center between the upper bending member 12 and the lower bending member 12.

Next, referring to FIGS. 2C and 2D, the bending work may be performed by rotating the upper and lower bending members 12.

As described above, when the bending member 12 is rotated, the moving member 14 coupled thereto may also be rotated to thus reduce an angle formed by the two moving members 14, thereby bending the panel 20 spanning the two moving members 14.

Here, the first bending position BP1 may be aligned at the center between the upper bending member 12 and the lower bending member 12, and the bending may be performed centering on the first bending position BP1.

Next, the upper and lower bending members 12 may be rotated in an opposite direction to enable the upper bending member 12 and the upper moving member 14 to be parallel to each other again.

The moving member 14 may then be moved to align the second bending position BP2 of the panel 20.

For example, referring to of FIGS. 2E and 2F, the moving member 14 may be moved upward to thus align the lower position BP2 among the three bending positions BP1, BP2, and BP3 of the panel 20 at the center between the upper bending member 12 and the lower bending member 12.

Here, an upper edge of the lower moving member 14 may be aligned with an upper edge of the lower bending member 12 or disposed lower than the upper edge of the lower bending member 12.

Next, referring to FIGS. 2G and 2H, the upper and lower bending members 12 may be rotated to thus perform the bending work on the second bending position BP2 of the panel 20.

Next, the upper and lower bending members 12 may be rotated in the opposite direction to enable the upper bending member 12 and the upper moving member 14 to be parallel to the lower bending member 12 and the lower moving member 14 again, and the moving member 14 may then be moved to align the third bending position BP3 of the panel 20.

For example, referring to of FIGS. 21 and 2J, the moving member 14 may be moved downward to thus align the upper position BP3 among the three bending positions BP1, BP2, and BP3 of the panel 20 at the center between the upper bending member 12 and the lower bending member 12.

Here, a lower edge of the upper moving member 14 may be aligned with a lower edge of the upper bending member 12 or disposed upper than the lower edge of the upper bending member 12.

Next, referring to FIGS. 2K and 2L, the upper and lower bending members 12 may be rotated to thus perform the bending work on the third bending position BP3 of the panel 20.

As described above, according to an embodiment of the present disclosure, the moving member 14 may be installed at the bending device 10, and the panel 20 may be fixed onto the moving member 14, and the bending work may then be performed by changing the bending position of the panel 20 by using the moving member 14.

In this way, it is possible to make the bending work simpler and easier than repeatedly loading and transferring the panel 20 by using a robot hand or the like as the bending position of the panel 20 is changed.

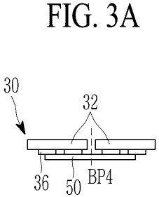

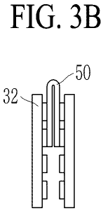

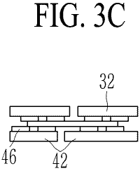

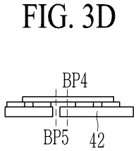

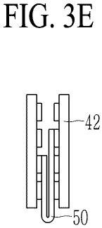

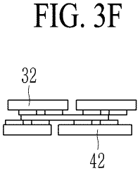

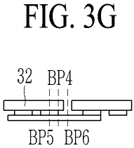

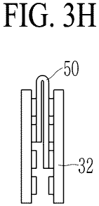

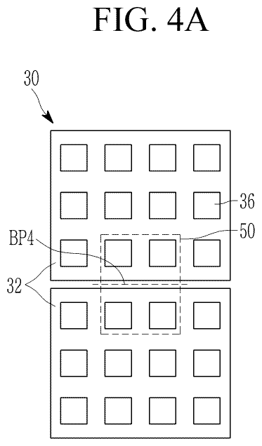

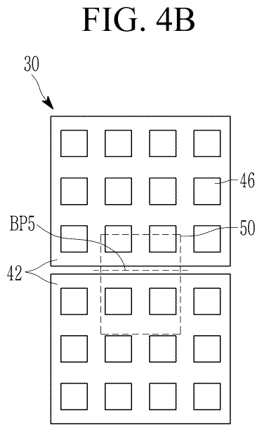

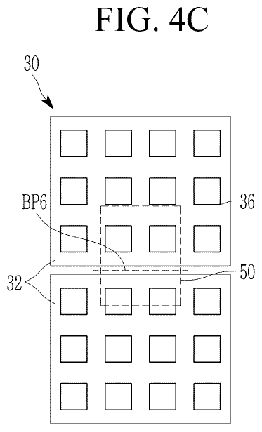

FIGS. 3A to 3H and FIGS. 4A to 4C are schematic views of the device and method for bending the panel according to another embodiment of the present disclosure.

FIGS. 3A to 3H are side views and FIGS. 4A to 4C are plan views.

Referring to FIGS. 3A to 3H and FIGS. 4A to 4C, a device 30 of bending the display device according to the present embodiment may include a plurality of upper-end bending members 32, a plurality of lower-end bending members 42, and a plurality of panel fixing members 36 and 46 respectively coupled to the bending members 32 and 42.

The upper-end bending member 32 and the lower-end bending member 42 may be vertically disposed based on a direction of gravity, that is, a vertical direction, and may independently perform the bending work.

The pair of upper-end bending members 32 may be spaced apart from each other at a distance (for example, in the second direction), and symmetric to each other (for example, with respect to a symmetry axis in the first direction).

At least one of the pair of upper-end bending members 32 may be rotated about, for example, the axis parallel to the horizontal direction, for example, downward.

A rotation axis of the upper-end bending member 32 may be disposed near an inner end of the upper-end bending member 32 in FIGS. 4A to 4C.

The maximum rotation angle of the upper-end bending member 32 may be about 90 degrees when both of the pair of upper-end bending members 32 are rotated, and the maximum rotation angle of the upper-end bending member 32 may be about 180 degrees when only one of the pair of upper-end bending members 32 is rotated.

In addition, at least one of the lower-end bending members 42 may be rotated about, for example, the axis parallel to the horizontal direction.

However, a rotation direction of the lower-end bending member 42 may be opposite to a rotation direction of the upper-end bending member 32.

That is, the lower-end bending member 42 may be rotated upward when the upper-end bending member 32 is rotated downward.

A rotation axis of the lower-end bending member 42 may be disposed near an inner end of the lower-end bending member 42 in FIGS. 4A to 4C.

In an embodiment, the maximum rotation angle of the lower-end bending member 42 may be about 90 degrees when both the pair of lower-end bending members 42 are rotated, and the maximum rotation angle of the lower-end bending member 42 may be about 180 degrees when only one of the pair of lower-end bending members 42 is rotated.

For example, each of the panel fixing members 36 and 46 may include the suction pad, and may be attached on surfaces of the upper-end and lower-end bending member 32 and 42, which are opposite to each other, that is, opposite surfaces thereof.

The panel fixing member 36 or 46 may fix the panel, on which the bending work is to be performed, using a method such as suction, for example.

The bending work may be performed as the panel is loaded onto the upper-end or lower-end bending member 32 or 42, the panel is fixed to the bending member 32 or 42 by using the panel fixing member 36 or 46, and then the upper-end or lower-end bending member 32 or 42 is rotated such that the panel 50 bends.

The bending work is described below in further detail.

In the present embodiment, the bending work may be performed continuously on several bending positions of the panel 50, such as three adjacent points.

First, as shown in FIGS. 3A and 4A, while the two upper-end or lower-end bending members 32 and 42 are disposed to be parallel to each other, for example, the panel 50 may be loaded onto the upper-end or lower-end bending member 32 or 42 of the bending device 30 by using the robot hand, and the panel 50 may be coupled to the upper-end or lower-end bending member 32 or 42 by using the panel fixing member 36 or 46.

The panel 50 may be loaded onto any of the upper-end and lower-end bending members 32 and 42, and here, for convenience of description, the panel 50 is described as being loaded onto the upper-end bending member 32.

Here, a first bending position BP4 of the panel 50 may be aligned to the center between the two upper-end bending members 32.

For example, the middle position BP4 among the three bending positions BP4, BP5, and BP6 of the panel 50 may be aligned to the center between the two upper-end bending members 32.

Next, referring to FIG. 4B, the bending work may be performed by rotating the upper-end bending member 32.

When the upper-end bending members 32 are rotated to thus reduce an angle formed by the two upper-end bending members 32, thereby bending the panel 50 that spans the two upper-end bending members 32.

Here, the first bending position BP4 may be aligned at the center between the two upper-end bending members 32, and the bending may be performed centering on the first bending position BP4.

Next, referring to FIG. 3C, the upper-end bending member 32 may be rotated in an opposite direction to enable the two upper-end bending members 32 to be parallel to each other again. Next, the lower-end bending member 42 may be aligned with the panel 50 and the upper-end bending member 32.

Here, the upper position BP5 among the three bending positions BP4, BP5, and BP6 of the panel 50 may be aligned at the center between the two lower-end bending members 42.

Next, referring to FIG. 3D and FIG. 4B, the panel 50 and the upper-end bending member 32 may be uncoupled from each other, and the panel 50 may be coupled to the lower-end bending member 42 by using the panel fixing member 46.

Next, referring to FIG. 3E, the lower-end bending member 42 may be rotated to thus perform the bending work on the second bending position BP5 of the panel 50.

The rotation direction of the lower-end bending member 42 may be opposite to the rotation direction of the upper-end bending member 32, and the bending on the second position of the panel 50 may also be performed in the opposite direction.

Next, referring to FIG. 3F, the lower-end bending member 42 may be rotated in the opposite direction to enable the two lower-end bending members 32 to be parallel to each other again. Next, the upper-end bending member 32 may be aligned with the panel 50 and the lower-end bending member 42.

Here, the lower position BP6 among the three bending positions BP4, BP5, and BP6 of the panel 50 may be aligned at the center between the two upper-end bending members 32.

Next, referring to FIG. 4G and FIG. 4C, the panel 50 and the upper-end bending member 42 may be uncoupled from each other, and the panel 50 may be coupled to the upper-end bending member 32 by using the panel fixing member 36.

Next, referring to FIG. 4H, the upper-end bending member 32 may be rotated to thus perform the bending work on the third bending position BP6 of the panel 50.

As described above, according to an embodiment of the present disclosure, the upper-end and lower-end bending members 32 and 42 may be installed, and the bending works may then be performed by alternately aligning the bending positions of the panel differently when loading the panel.

In this way, it is possible to make the bending work simpler and easier than repeatedly loading and transferring the panel 50 by using the robot hand or the like as the bending position of the panel 50 is changed.

What is claimed is:

1. A device of bending a panel for a display device, the device comprising:
a plurality of bending members; and
a plurality of moving members coupled to the bending members to be movable and configured to mount the panel thereon,
wherein the panel, mounted on the moving members, bends as the bending members are rotated, and
a bending position of the panel mounted on the moving members is changed as the moving members are moved.

2. The device of claim 1, wherein the plurality of bending members comprises:
a first bending member;
a second bending member spaced apart from the first bending member in a first direction, and symmetric to the first bending member with respect to a first symmetry axis in a second direction perpendicular to the first direction;
a third bending member spaced apart from the first bending member in the second direction, and symmetric to the first bending member with respect to a second symmetry axis in the first direction; and
a fourth bending member spaced apart from the third bending member in the first direction, symmetric to the third bending member with respect to the first symmetry axis, spaced apart from the second bending member in the second direction, and symmetric to the second bending member with respect to the second symmetry axis.

3. The device of claim 2, wherein the first bending member and the second bending member are fixed to each other, and are rotatable about a first rotation axis in the second direction.

4. The device of claim 3, wherein the third bending member and the fourth bending member are fixed to each other, and are rotatable about a second rotation axis in the second direction, and
the plurality of moving members is between the plurality of bending members.

5. The device of claim 4, wherein the plurality of bending members comprises:
a first bending member;
a second bending member spaced apart from and parallel to the first bending member in a first direction;
a third bending member spaced apart from and parallel to the first bending member in a second direction perpendicular to the first direction; and
a fourth bending member spaced apart from and parallel to the third bending member in the first direction, and spaced apart from and parallel to the second bending member in the second direction, and
the plurality of moving members comprises:
a first moving member coupled between the first bending member and the second bending member; and
a second moving member coupled between the third bending member and the fourth bending member.

6. The device of claim 5, wherein the first bending member and the second bending member are fixed to each other, and are rotatable about a first rotation axis in the second direction.

7. The device of claim 6, wherein the third bending member and the fourth bending member are fixed to each other, and are rotatable about a second rotation axis in the second direction.

8. The device of claim 5, wherein the first moving member and the second moving member are movable in the second direction.

9. The device of claim 8, wherein a distance between the first moving member and the second moving member is maintained constant.

10. The device of claim 8, wherein a shortest distance between the first moving member and the second moving member is longer than a shortest distance between the first or second bending member and the third or fourth bending member.

11. The device of claim 10, wherein a boundary of the first moving member in the second direction does not exceed a boundary of the first or second bending member in the second direction, and a boundary of the second moving member in the second direction does not exceed a boundary of the third or fourth bending member in the second direction.

12. The device of claim 1, further comprising a panel fixing member attached to a surface of the moving member and fixing the panel mounted on the moving member.

13. A device of bending a panel for a display device, the device comprising:
a pair of first bending members, and
a pair of second bending members on a different surface from the first bending member,
wherein the panel, mounted on the first bending member, bends as the first bending member is rotated,
the panel, mounted on the second bending member, bends as the second bending member is rotated, and
the panel is mounted on the first bending member or the second bending member by being aligned while having different bending positions.

14. The device of claim 13, further comprising:
a first panel fixing member attached to a first surface of the first bending member and fixing the panel mounted on the first bending member; and
a second panel fixing member attached to a second surface of the second bending member and fixing the panel mounted on the second bending member,
wherein the first surface of the first bending member and the second surface of the second bending member are opposite to each other.

15. The device of claim 14, wherein
the pair of first bending members are spaced apart from each other in a first direction, and at least one of the pair of first bending members is rotatable about a rotation axis in a second direction perpendicular to the first direction, and
the pair of second bending members are spaced apart from each other in the first direction, and at least one of the pair of second bending members is rotatable about the rotation axis in the second direction.

16. A method of bending a panel for a display device, the method comprising:
loading the panel on a moving member coupled to a bending member;
bending the panel centering on a first bending position by rotating the bending member;
primarily moving the moving member with respect to the bending member; and
bending the panel centering on a second bending position, different from the first bending position, by rotating the bending member.

17. The method of claim 16, further comprising:
secondarily moving the moving member with respect to the bending member; and
bending the panel centering on a third bending position, different from the first and second bending positions, by rotating the bending member.

18. The method of claim 17, wherein the first bending position is between the second bending position and the third bending position.

19. The method of claim 17, wherein the panel is fixed to the moving member by a suction pad attached to the moving member.

20. A device of bending a panel for an electronic device, the device comprising:
a plurality of bending members; and
a plurality of moving members coupled to the bending members to be movable and configured to mount the panel thereon,
wherein the panel, mounted on the moving members, bends as the bending members are rotated, and
a bending position of the panel mounted on the moving members is changed as the moving members are moved.
